(19) United States
(12) Patent Application Publication
(10) Pub. No.: US 2009/0237089 A1
(43) Pub. Date: Sep. 24, 2009

(54) APPARATUS FOR TRANSFERRING PACKAGED CHIPS, TEST HANDLER AND METHOD FOR MANUFACTURING PACKAGED CHIPS

(76) Inventors: Jae Kyung CHO, Nam-gu (KR); Hae Jun Park, Asan-si (KR)

Correspondence Address: KED & ASSOCIATES, LLP, P.O. Box 221200, Chantilly, VA, 20153-1200, US

(21) Appl. No.: 12/339,873

(22) Filed: Dec. 19, 2008

(30) Foreign Application Priority Data
Mar. 24, 2008 (KR) 10-2008-0026895

(51) Int. Cl. G01R 31/28

(52) U.S. Cl. 324/555; 324/537

(57) ABSTRACT

An apparatus for transferring packaged chips, a test handler, and a method for manufacturing packaged chips are provided. The apparatus for transferring packaged chips may include a main frame having a coupling member coupled to a base plate and a supporting member coupled to the coupling member, a plurality of first pickers coupled to one side of the supporting member so as to be movable in a horizontal direction, a plurality of second pickers coupled to the other side of the supporting member so as to be movable in the horizontal direction, and a control unit to determine distances by which the first pickers and the second pickers move in the horizontal direction.

### BACKGROUND

1. Field

Embodiments of the present invention may relate to a test handler for connecting packaged chips to be tested to a tester and classifying packaged chips tested by the tester by grades based on the test result.

2. Background

A test handler may perform electrical tests on packaged chips at a conclusion of a packaging process.

The test handler may be connected to a particular tester for testing packaged chips. The tester may include a hi-fix board having a plurality of test sockets to connect to the packaged chips. The hi-fix board may be coupled to the test handler.

The test handler may perform a loading process, an unloading process and a testing process by use of a test tray including a plurality of containing units that contain the packaged chips.

The packaged chips to be tested in a user tray may be transferred from the user tray to a test tray in the loading process. The transferring of the packaged chips to be tested in the loading process may be carried out by an apparatus for transferring packaged chips.

The apparatus for transferring packaged chips may pick up the packaged chips to be tested from the user tray and provide the picked-up packaged chips to a test tray. The apparatus for transferring packaged chips may include a picker that can suck and attach (or fix) to the packaged chips.

The packaged chips contained in the test tray in the loading process may be connected to test sockets in the testing process. The tester may test the packaged chips to determine electrical characteristics of the packaged chips connected to the hi-fix board.

The test handler may include a plurality of chambers that are capable of heating or cooling the packaged chips so the tester may determine whether the packaged chips operate normally under environments of high temperature, low temperature and normal temperature.

The packaged chips tested in the testing process may be transferred from the test tray to the user tray in the unloading process. The transferring of the tested packaged chips in the unloading process may be carried out by the apparatus for transferring packaged chips.

The apparatus for transferring packaged chips may pick up the tested packaged chips from the test tray and provide the picked-up packaged chips to the corresponding user trays by grades based on the test result.

The packaged chips may be provided in the user tray and the test tray and having different gaps.

### BRIEF DESCRIPTION OF THE DRAWINGS

Arrangements and embodiments may be described in detail with reference to the following drawings in which like reference numerals refer to like elements and wherein:

FIGS. 1 and 2 are front views illustrating a state where an apparatus for transferring packaged chips adjusts gaps between packaged chips;

FIG. 3 is a perspective view illustrating an apparatus for transferring packaged chips according to an example embodiment of the present invention;

FIG. 4 is an exploded perspective view illustrating an apparatus for transferring packaged chips according to an example embodiment of the present invention as viewed in a direction arrow H in FIG. 3;

FIG. 5 is an exploded perspective view illustrating an apparatus for transferring packaged chips according to an example embodiment of the present invention as viewed in a direction arrow I in FIG. 3;

FIG. 6 is a perspective view illustrating a second picker of an apparatus for transferring packaged chips according to an example embodiment of the present invention;

FIG. 7 is a perspective view illustrating a state where a first picker and a second picker of an apparatus for transferring packaged chips according to an example embodiment of the present invention are coupled to a supporting member;

FIG. 8 is an exploded perspective view illustrating a first picker, a second picker, and a supporting member as viewed in a direction of arrow j in FIG. 7;

FIG. 9 is a plan view schematically illustrating a test handler according to an example embodiment of the present invention;

FIG. 10 is a diagram schematically illustrating a path through which a test tray is transferred between a loading unit, an unloading unit and an exchanging unit in a test handler according to an example embodiment of the present invention; and

FIG. 11 is a front view schematically illustrating a loading unit, an unloading unit and an exchanging unit in a test handler according to an example embodiment of the present invention.

### DETAILED DESCRIPTION

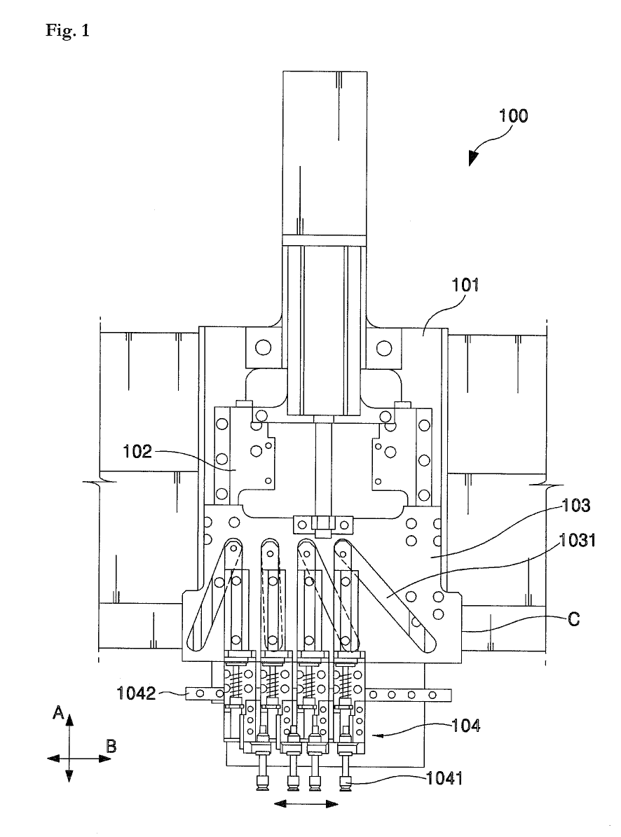

FIGS. 1 and 2 are front views illustrating states where an apparatus for transferring packaged chips adjusts gaps of packaged chips.

Referring to FIGS. 1 and 2, an apparatus for transferring packaged chips 100 according to an example arrangement may include a base plate 101, an ascending/descending plate 102, a guide plate 103 and a picker 104.

The base plate 101 may support the ascending/descending plate 102, the guide plate 103 and the picker 104. The base plate 101 may move in a horizontal direction. As the base plate 101 moves, the apparatus for transferring packaged chips 100 may transfer the packaged chips in the loading process and the unloading process.

The ascending/descending plate 102 may be coupled to the base plate 101 to be movable in a vertical direction (i.e., a direction of arrow A). As the ascending/descending plate 102 moves, the apparatus for transferring packaged chips 100 may pick up the packaged chips from the user tray or the test tray and provide the picked-up packaged chips to the user tray or the test tray in the loading process and the unloading process.

The guide plate 103 may be coupled to the ascending/descending plate 102 to be movable in the vertical direction (i.e., the direction of arrow A). A plurality of guide holes 1031 may be formed in the guide plate 103 and may be tilted with different slopes and the pickers 104 may be movably coupled to the guide holes 1031, respectively.

The pickers 104 may be coupled to the ascending/descending plate 102 to be movable in a horizontal direction (i.e., a direction of arrow B). The pickers 104 may include nozzles 1041 that can suck and attach (or fix) the packaged chips. The apparatus for transferring packaged chips 100 may include a plurality of pickers 104 as much as a number of packaged chips that can be transferred at a same time.

The pickers 104 may be movably coupled to the guide holes 1031, respectively. When the guide plate 103 moves in the vertical direction (i.e., direction of arrow A), the pickers 104 may move in the horizontal direction (i.e., direction of arrow B) along slopes of the guide holes 1031 to adjust the gaps.

As shown in FIG. 1, when the guide plate 103 is located at a first position C, the gaps of the pickers 104 may be a minimum. As shown in FIG. 2, when the guide plate 103 is located at a second position D, the gaps of the pickers 104 may be a maximum. Accordingly, the apparatus for transferring packaged chips 100 can adjust the gaps of the packaged chips in the loading process and the unloading process.

The pickers 104 may be move in the horizontal direction (i.e., direction of arrow B) along guide rails 1042 disposed in the ascending/descending plate 102. Guide blocks (not shown) movable coupled to the guide rails 1042 may be disposed in the pickers 104. The movement in the horizontal direction (i.e., the direction of arrow B) of the pickers 104 may be guided by the guide rails 1042, thereby to adjust the gaps.

The test handlers classify packaged chips by grades for a short amount of time. For this purpose, more packaged chips may be connected to the test sockets at a same time to provide the more packaged chips to the test tray.

As the number of packaged chips to be provided in the test tray increases, the time for the loading process and the unloading process may increase. To minimize an increase in time, the apparatus for transferring packaged chips 100 may transfer more packaged chips at a same time. That is, a greater number of pickers 104 may be coupled to the ascending/descending plate 102.

However, when the number of pickers increases, the apparatus for transferring packaged chips 100 may have the following problems and/or disadvantages.

As the number of pickers increases, a size of the ascending/descending plate 102 may also increase and thus a size of the apparatus for transferring packaged chips 100 may increase accordingly. The increase in size of the apparatus for transferring packaged chips 100 may mean an increase in weight, which may affect speed at which the packaged chips are transferred in the loading process and the unloading process. As a result, a goal of classifying more packaged chips for a short amount of time may not be accomplished.

To minimize the increase in size of the ascending/descending plate 102 while increasing the number of pickers 104, a width 104L (FIG. 2) of the pickers 104 may be reduced. When the width 104L (FIG. 2) of the pickers 104 is reduced, the width of the guide blocks movably coupled to the guide rails 1042 may also be reduced.

Accordingly, a coupling force between the pickers 104 and the guide rails 1042 may be weakened and a function of the guide rails 1042 guiding movement of the pickers 104 may deteriorate. Therefore, the pickers 104 may not move while maintaining the accurate gaps, thereby deteriorating a function of the apparatus for transferring packaged chips 100 of accurately adjusting gaps of packaged chips.

Embodiments may provide an apparatus for transferring packaged chips that is capable of transferring more packaged chips at a same time and that accurately adjusts gaps of the packaged chips.

A test handler may be provided that is capable of performing a loading process, a testing process and an unloading process on more packaged chips for a short amount of time.

A method for manufacturing packaged chips may be provided that is capable of manufacturing more packaged chips for a short amount of time, thereby strengthening competitive power of products such as cost reduction.

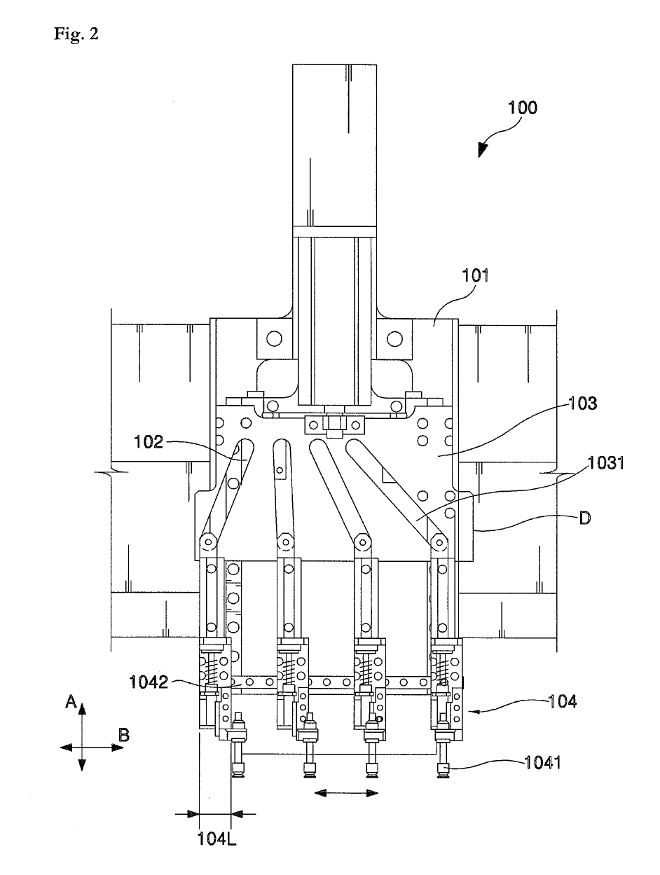

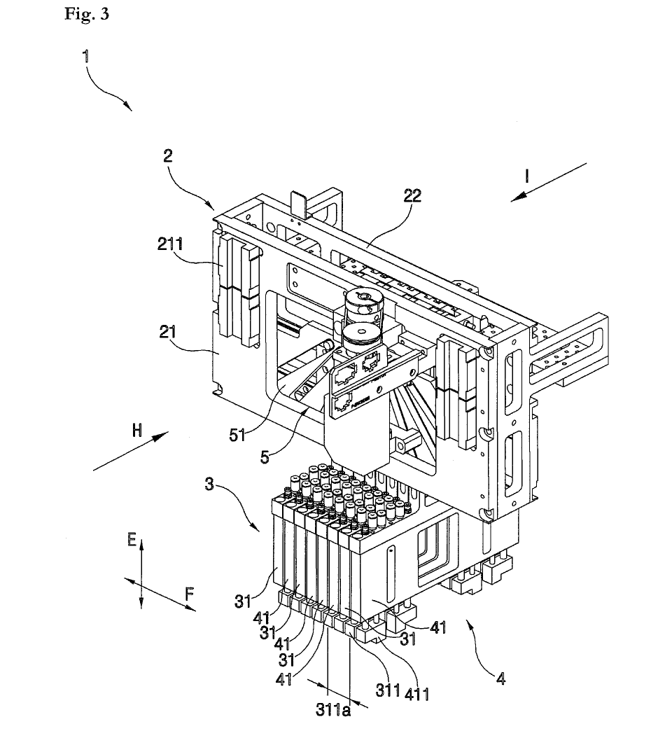

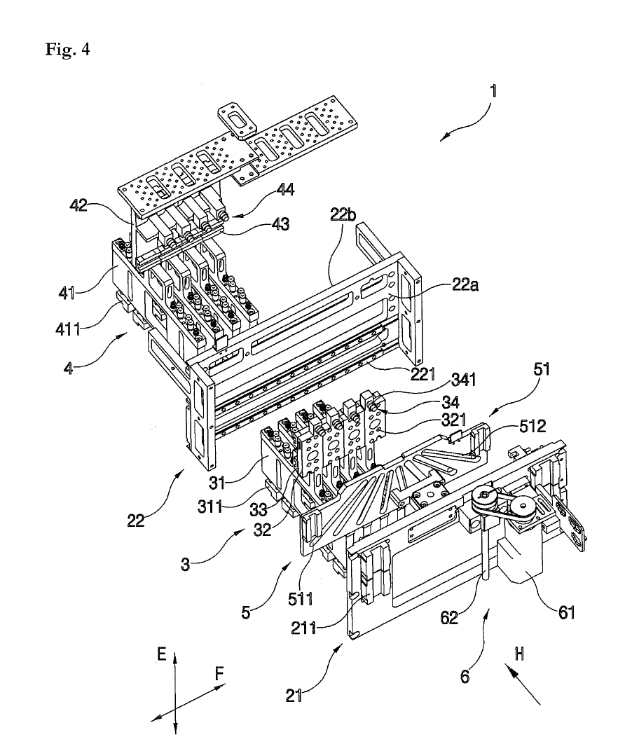

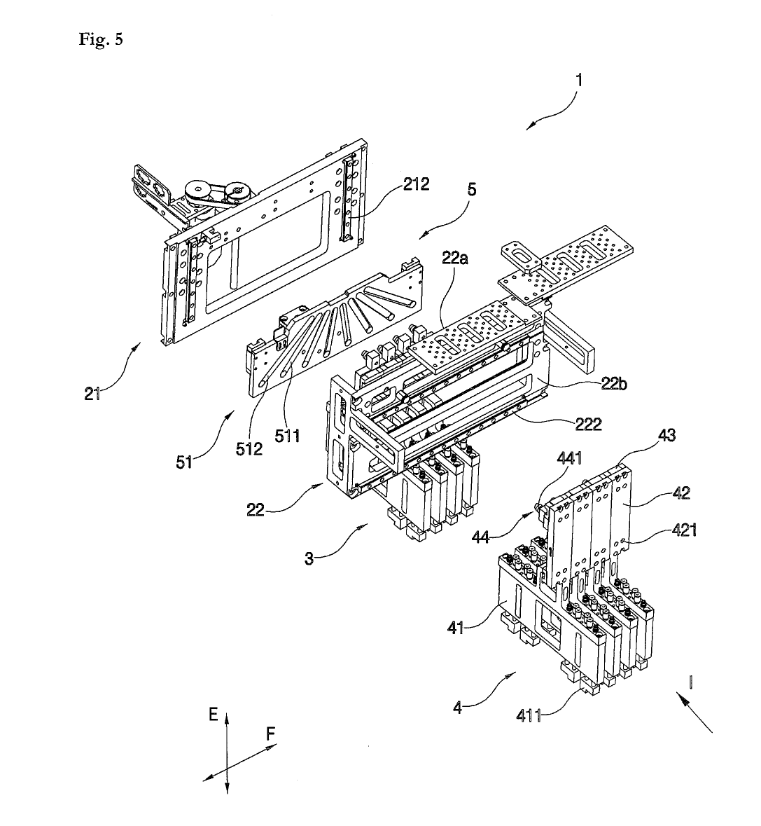

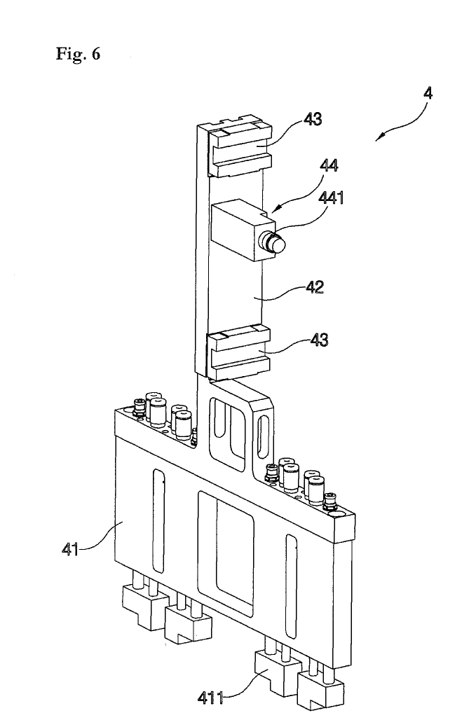

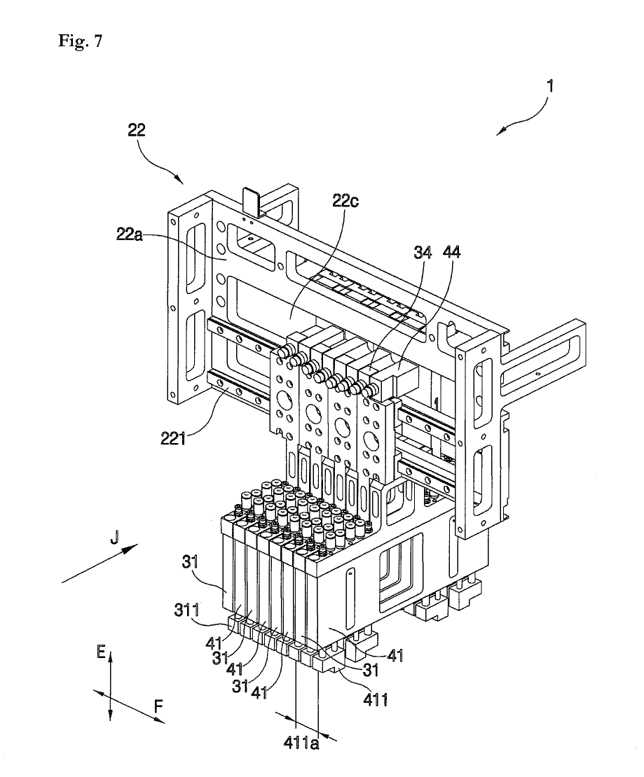

FIG. 3 is a perspective view illustrating an apparatus for transferring packaged chips according to an example embodiment of the present invention. FIG. 4 is an exploded perspective view illustrating an apparatus for transferring packaged chips according to an example embodiment of the present invention as viewed in a direction arrow H in FIG. 3. FIG. 5 is an exploded perspective view illustrating an apparatus for transferring packaged chips according to an example embodiment of the present invention as viewed in a direction arrow I in FIG. 3. FIG. 6 is a perspective view illustrating a second picker of an apparatus for transferring packaged chips according to an example embodiment of the present invention. FIG. 7 is a perspective view illustrating a state where a first picker and a second picker of an apparatus for transferring packaged chips according to an example embodiment of the present invention are coupled to a supporting member. FIG. 8 is an exploded perspective view illustrating a first picker, a second picker and a supporting member as viewed in a direction of arrow j in FIG. 7.

Referring to FIGS. 3 and 4, an apparatus for transferring packaged chips 1 according to an example embodiment of the present invention may include a main frame 2, a first picker 3, a second picker 4 and a control unit 5.

The main frame 2 may include a coupling member 21 and a supporting member 22.

The coupling member 21 may be coupled to a base plate (not shown) to be movable in a vertical direction (i.e., a direction of arrow E).

The main frame 2 may move in the vertical direction (i.e., direction of arrow E) as the coupling member 21 moves in the vertical direction (i.e., the direction of arrow E). Accordingly, the apparatus for transferring packaged chips 1 may pick up packaged chips from a user tray or a test tray and provide the packaged chips to the user tray or the test tray, at a time of performing a loading process or an unloading process.

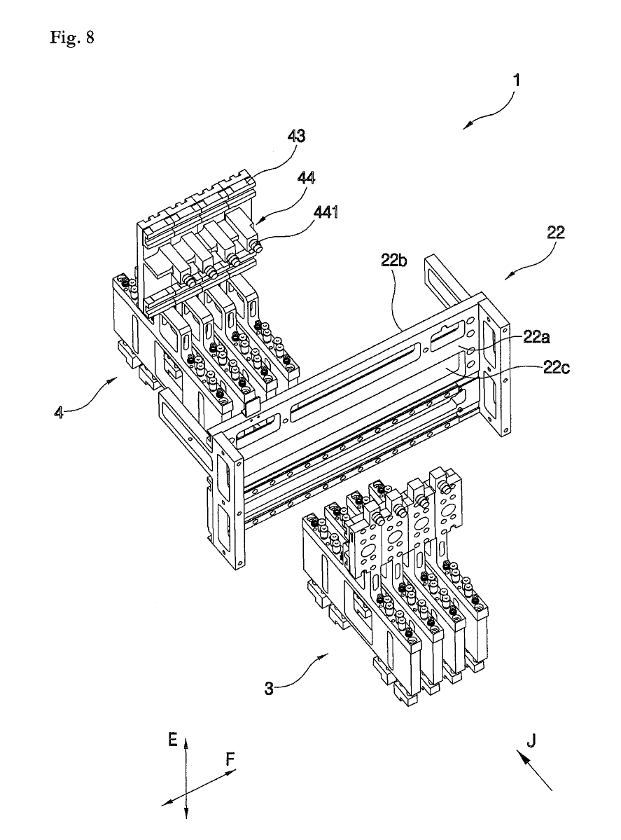

The base plate (not shown) to which the coupling member 21 is coupled may move in or along an X axis direction and a Y axis direction (FIG. 9). As the base plate (not shown) moves, the apparatus for transferring packaged chips 1 may transfer the packaged chips at the time of performing the loading process and the unloading process.

The supporting member 22 may be coupled to the coupling member 21. Accordingly, when the coupling member 21 moves in the vertical direction (i.e., the direction of arrow E), the supporting member 22 can move in the vertical direction (i.e., the direction of arrow E).

Referring to FIGS. 3 to 5, the coupling member 21 may include a coupling guide block 211 and a vertical guide rail 212.

The coupling guide block 211 may be coupled to an ascending/descending guide rail (not shown) disposed in the base plate (not shown) to be movable in the vertical direction (i.e., the direction of arrow E). The coupling member 21 may include a plurality of coupling guide blocks 211. The ascending/descending guide rail may guide movement in the vertical direction (i.e., the direction of arrow E) of the coupling member 21.

Accordingly, the apparatus for transferring packaged chips 1 may accurately pick up the packaged chips from the user tray or the test tray and can accurately contain the packaged chips in the user tray and the test tray at a time of performing the loading process and the unloading process.

The control unit 5 may be coupled to the vertical guide rail 212 to be movable in the vertical direction (i.e., the direction of arrow E). The coupling member 21 may include a plurality of vertical guide rails 212. The vertical guide rails 212 may guide movement in the vertical direction (i.e., the direction of arrow E) of the control unit 5.

The coupling member 21 may be provided with an operating unit 6 to supply power for allowing the control unit 5 to move in the vertical direction (i.e., the direction of arrow E). The operating unit 6 can include a motor 61 and a ball screw 62.

Referring to FIGS. 3 to 5, the supporting member 22 may be coupled to the coupling member 21. The first picker 3 and the second picker 4 may be coupled to the supporting member 22 to be movable in a horizontal direction (i.e., a direction of arrow F).

A plurality of first pickers 3 may be coupled to one side 22a of the supporting member 22 to be movable in the horizontal direction (i.e., the direction of arrow F) and a plurality of second pickers 4 may be coupled to the other side 22b of the supporting member 22 to be movable in the horizontal direction (i.e., the direction of arrow F). Accordingly, the area of the supporting member 22 to which the first pickers 3 and the second pickers 4 are movably coupled may be distributed to one side 22a and the other side 22b.

Accordingly, even when a number of pickers increases for the apparatus for transferring packaged chips 1 to transfer more packaged chips at a same time, an increase in size and weight of the apparatus for transferring packaged chips 1 may be minimized. In addition, since the coupling force of the first pickers 3 and the second pickers 4 to the supporting member 22 may be prevented from being weakened, the apparatus for transferring packaged chips 1 may be provided that is capable of accurately adjusting gaps between the packaged chips.

The supporting member 22 may include a first guide rail 221 and a second guide rail 222.

The first guide rail 221 may be provided on one side 22a of the supporting member 22 and the first pickers 3 may be coupled thereto to be movable in the horizontal direction (i.e., the direction of arrow F). The first guide rail 221 may guide movement of the first pickers 3. The supporting member 22 may be provided with at least one first guide rail 221.

The second guide rail 222 may be provided on the other side 22b of the supporting member 22 and the second pickers 4 may be coupled thereto to be movable in the horizontal direction (i.e., the direction of arrow F). The second guide rail 222 may guide movement of the second pickers 4. The supporting member 22 may be provided with at least one second guide rail 222.

The second guide rail 222 can be provided on the other side 22b of the supporting member 22 opposite the one side 22a on which the first guide rail 221 is provided.

Referring to FIGS. 3 to 5, the first pickers 3 may be coupled to one side 22a of the supporting member 22 to be movable in the horizontal direction (i.e., the direction of arrow F). A plurality of first pickers 3 may be coupled to the one side 22a of the supporting member 22. The first pickers 3 may be coupled to a surface of the supporting member 22 that is opposite the surface to which the second pickers 4 are coupled.

Accordingly, the first pickers 3 can be coupled to the supporting member 22 with a greater area. As a result, even when the number of pickers increases for the apparatus for transferring packaged chips 1 to transfer more packaged chips at a same time, the first pickers 3 may be coupled to the supporting member 22 with sufficient coupling power and thus can move with an accurate gap maintained therebetween.

The first picker 3 may include a first nozzle frame 31, a first coupling frame 32, a first guide block 33 and a first moving member 34.

The first nozzle frame 31 may be provided with at least one first nozzle 311 that comes into contact with the packaged chip. The first nozzle 311 can suck and attach (or fix) to the packaged chip.

As shown in FIG. 3, the first picker 3 can be coupled to the supporting member 22 in such a manner that the second picker 4 is arranged aside the first nozzle frame 31. That is, the first pickers 3 may be coupled to the supporting member 22 so that the gap 311a in the horizontal direction (i.e., the direction of arrow F) of the first nozzle 311 is greater than the gap of the packaged chips provided in the user tray or the test tray.

Accordingly, a large area can be assigned to each first picker 3 at a time of coupling the first picker 3 to the one side 22a of the supporting member 22.

The first coupling frame 32 may be movably coupled to the one side 22a of the supporting member 22. The first coupling frame 32 and the first nozzle frame 31 may be monolithically formed. The first coupling frame 32 may be provided with the first guide block 33.

A plurality of first pickers 32 may be coupled to the one side 22a of the supporting member 22 so that the first coupling frame 32 of one first picker 3 is arranged aside another first coupling frame 32 of another first picker 3. That is, the first coupling frame 32 of one first picker 3 can be arranged aside the first coupling frame 32 of another first picker 3 and the second picker 4 can be arranged aside the first nozzle frame 31.

Accordingly, since the first coupling frame 32 can be made to have a sufficient size, the first pickers 3 can be coupled to the supporting member 22 with sufficient coupling power. As a result, the first pickers 3 and the second pickers 4 can be accurately adjusted with a gap corresponding to the gaps of the packaged chips contained in the user tray or the test tray.

The first guide block 33 may be coupled to the first coupling frame 32 and may be movably coupled to the first guide rail 221. Accordingly, the first pickers 3 may be guided to move in the horizontal direction (i.e., the direction of arrow F) by the first guide rail 221. A plurality of first guide blocks 33 may be coupled to the first coupling frame 32.

Since the first guide block 33 can be manufactured to have a sufficient size similarly to the first coupling frame 32, a plurality of coupling grooves (not shown) may be formed in the first guide block 33 and a plurality of first coupling holes 321 can be provided in the first coupling frame 32.

Accordingly, since the first guide block 33 and the first coupling frame 32 can be strongly coupled to each other with coupling means (such as bolts), the first pickers 3 can move with accurate gaps maintained even when the gaps are repeatedly adjusted for a long amount of time.

The first moving member 34 may be movably coupled to the control unit 5. The first moving member 34 may move based on the control unit 5 and thus the gap of the first pickers 3 can be adjusted in the horizontal direction (i.e., the direction of arrow F).

The first moving member 34 may be formed to protrude from the first coupling frame 32 toward the control unit 5. The first moving member 34 may include a first rotating member 341.

The first rotating member 341 may be rotatably coupled to a portion of the first moving member 34 that comes into contact with the control unit 5. The first rotating member 341 can rotate with movement of the first moving member 34 and thus prevent (or reduce) the first moving member 34 and the control unit 5 from being abraded or damaged due to friction.

Referring to FIGS. 6 to 8, the second picker 4 may be coupled to the other side 22b of the supporting member 22 in the horizontal direction (i.e., the direction of arrow F). A plurality of second pickers 4 may be coupled to the other side 22b of the supporting member 22. The second pickers 4 can be coupled to a surface of the supporting member 22 that is opposite the surface to which the first pickers 3 are coupled.

Accordingly, the second pickers 4 can be coupled to the supporting member 22 with large areas. As a result, even when the number of pickers increases, the second pickers 4 can be coupled to the supporting member 22 with sufficient coupling power and can move with an accurate gap maintained therebetween.

The second picker 4 may include a second nozzle frame 41, a second coupling frame 42, a second guide block 43 and a second moving member 44.

The second nozzle frame 41 may be provided with at least one second nozzle 411 that comes into contact with the packaged chip. The second nozzle 411 can suck and attach (or fix) to the packaged chip.

As shown in FIG. 7, a plurality of second pickers 4 can be coupled to the supporting member 22 so that the first nozzle frame 31 is arranged aside the second nozzle frame 41. That is, the second pickers 4 can be coupled to the supporting member 22 so that the gap 411a in the horizontal direction (i.e., the direction of arrow F) of the second nozzles 411 is greater than the gap of the packaged chips provided in the user tray or the test tray.

Accordingly, when the second pickers 4 are coupled to the other side 22b of the supporting member 22, larger areas can be assigned to the second pickers 4.

Referring to FIGS. 6 to 8, the second nozzles 411 and the first nozzles 311 can be in the form of a matrix having a predetermined gap. The gap between the second nozzles 411 and the first nozzles 311 may be substantially equal to the gap between the packaged chips contained in the user tray or the test tray. The matrix formed by the second nozzles 411 and the first nozzles 311 can correspond to the number of packaged chips that can be picked up at a same time by the apparatus for transferring packaged chips 1.

The second coupling frame 42 may be movably coupled to the other side 22b of the supporting member 22. The second coupling frame 42 and the second nozzle frame 41 may be monolithically manufactured. The second coupling frame 42 may be provided with the second guide block 43.

A plurality of second pickers 42 can be coupled to the other side 22b of the supporting member 22 so that the second coupling frame 42 of one second picker 4 may be arranged aside the second coupling frame 42 of another second picker 4. That is, the second coupling frame 42 of one second picker 4 may be arranged aside the second coupling frame 42 of another second picker 4 and the first nozzle frame 31 may be arranged aside the second nozzle frame 41.

Accordingly, since the second coupling frame 42 can be manufactured with a sufficient size, the second pickers 4 can be coupled to the supporting member 22 with sufficient coupling power. As a result, the second pickers 4 and the first pickers 3 can be controlled to have a gap corresponding to the gap of the packaged chips provided in the user tray or the test tray.

Referring to FIGS. 3 and 6 to 8, the second guide block 43 may be coupled to the second coupling frame 42 and may be movably coupled to the second guide rail 222. Accordingly, the second pickers 4 may be guided to move in the horizontal direction (i.e., direction of arrow F) by the second guide rail 222. The plurality of second guide blocks 43 can be coupled to the second coupling frame 42.

Since the second guide block 43 can be manufactured to have a sufficient size similarly to the second coupling frame 42, a plurality of second coupling grooves (not shown) can be formed in the second guide block 43 and a plurality of second coupling holes 421 (FIG. 5) can be formed in the second coupling frame 42.

Accordingly, the second guide block 43 and the second coupling frame 42 may be strongly coupled to each other by coupling means, such as bolts. As a result, even when the gap of the second pickers 4 is repeatedly adjusted for a long time, the second pickers 4 may move with an accurate gap maintained therebetween.

The second moving member 44 may be movably coupled to the control unit 5. The second moving member 44 may move based on the control unit 5 and thus the gap of the second pickers 4 may be adjusted in the horizontal direction (i.e., the direction of arrow F).

The second moving member 44 can be formed to protrude from the second coupling frame 42 toward the control unit 5. The second moving member 44 can be formed to protrude with a length enough to be coupled to the control unit 5. A hole 22c through which the second moving member 44 passes may be formed in the supporting member 22.

When the second pickers 4 and the first pickers 3 are coupled to the supporting member 22 as shown in FIG. 7, the second moving members 44 and the first moving member 34 can protrude toward the control unit 5 (FIG. 4) with substantially a same length.

Accordingly, the gaps of the first pickers 3 and the second pickers 4 may be adjusted at a same time by use of one control unit 5. As a result, a simple structure may be provided to easily and accurately adjust the gaps of the first pickers 3 and the second pickers 4.

The second moving member 44 may include a second rotating member 441. The second rotating member 441 can be rotatably coupled to a portion of the second moving member 44 that comes into contact with the control unit 5. The second rotating member 441 can rotate with movement of the second moving member 44 and thus may prevent (or reduce) the second moving member 44 and the control unit 5 from being abraded and damaged due to friction.

Referring to FIGS. 3 to 5, the control unit 5 may determine the distances by which the first pickers 3 and the second pickers 4 move in the horizontal direction (i.e., the direction of arrow F), respectively. That is, the first pickers 3 and the second pickers 4 may move by a predetermined distance to adjust the gaps therebetween based on the control unit 5. Accordingly, the apparatus for transferring packaged chips can adjust the gap of the packaged chips at the time of performing the loading process and the unloading process.

Although not shown, the control unit 5 may include a plurality of linkage members. The linkage members may interlock with each other to determine distances by which the first pickers 3 and the second pickers 4 move in the horizontal direction (i.e., the direction of arrow F).

As shown in FIGS. 3 to 5, the control unit 5 may include a guide plate 51 coupled to the coupling member 21 to be movable in the vertical direction (i.e., the direction of arrow E).

A plurality of first guide holes 511 to which the first pickers 3 are movably coupled and a plurality of second guide holes 512 to which the second pickers 4 are movably coupled may be formed in the guide plate 51.

The first guide holes 511 and the second guide holes 512 may be formed in the guide plate 51 so that the second guide hole 512 may be arranged aside the first guide hole 511. The first guide holes 511 and the second guide holes 512 may be tilted with different slopes.

The first moving members 34 can be movably coupled to the first guide holes 511. With movement of the first moving members 34 along the first guide holes 511, the gap of the first pickers 3 can be adjusted.

The second moving members 44 can be movably coupled to the second guide holes 512. With movement of the second moving members 44 along the second guide holes 512, the gap of the second pickers 4 can be adjusted.

When the guide plate 51 moves in the vertical direction (i.e., the direction of arrow E) by the operating unit 6, the first moving members 34 and the second moving members 44 move along the first guide holes 511 and the second guide holes 512, respectively, and thus the gap of the first pickers 3 and the gap of the second pickers 4 can be adjusted.

As shown in FIG. 3, when the guide plate 51 moves down, the first moving members 34 and the second moving members 44 move upward in the first guide holes 511 and the second guide holes 512 and thus the gaps of the first pickers 3 and the second pickers 4 can be narrowed. When the guide plate 51 moves to the lowermost position, the gaps of the first pickers 3 and the second pickers 4 can be adjusted to a minimum.

When the guide plate 51 moves upward, the first moving members 34 and the second moving members 44 move downward in the first guide holes 511 and the second guide holes 512 and thus the gaps of the first pickers 3 and the second pickers 4 may be widened. When the guide plate 51 moves to the uppermost position, the gaps of the first pickers 3 and the second pickers 4 may be adjusted to a maximum.

As shown in FIG. 5, this may be because the first guide holes 511 and the second guide holes 512 are tilted downward to increase the gap therebetween. When the first guide holes 511 and the second guide holes 512 are obliquely formed to decrease the gap downward, the opposite of the above description may be true.

A test handler according to an example embodiment may now be described with reference to the accompanying drawings.

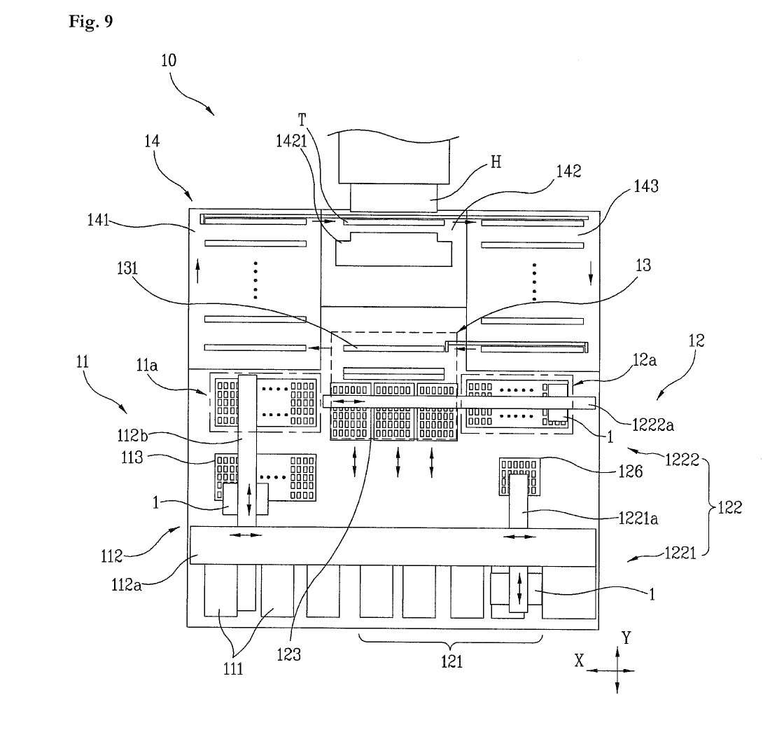

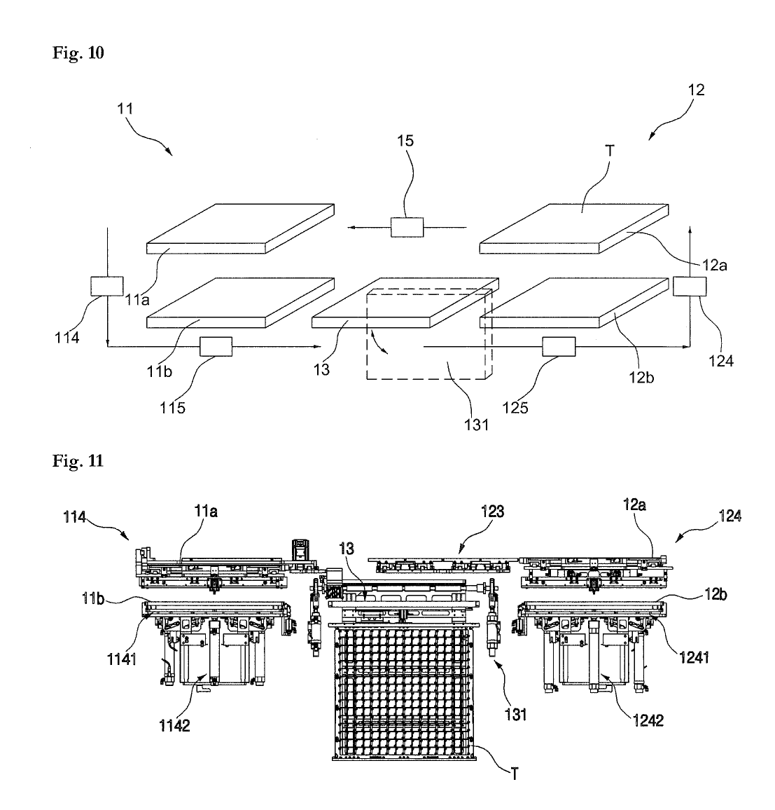

FIG. 9 is a plan view schematically illustrating a test handler according to an example embodiment of the present invention. FIG. 10 is a diagram schematically illustrating a path through which a test tray is transferred between a loading unit, an unloading unit and an exchanging unit in a test handler according to an example embodiment of the present invention. FIG. 11 is a front view schematically illustrating a loading unit, an unloading unit and an exchanging unit in a test handler according to an example embodiment of the present invention. Reference numerals denoting the test trays in FIG. 10 may indicate elements of the test handler in which the test trays are located.

Referring to FIGS. 9 and 10, the test handler 10 according to an example embodiment may include a loading unit 11, an unloading unit 12, a passage site 13, a chamber unit 14 and a transferring unit 15.

The loading unit 11 may perform a loading process of containing packaged chips to be tested in a test tray T. The loading unit 11 may be provided with the above-described apparatus for transferring packaged chips 1.

The loading unit 11 may include a loading stacker 111, a loading picker 112, a loading buffer 113 and a loading transferring unit.

The loading stacker 111 may store a plurality of user trays containing the packaged chips to be tested.

The loading picker 112 may perform the loading process on the test tray T located at a loading position 11a. At a time of containing the packaged chips to be tested in the test tray T, the test tray T may be located at the loading position 11a. The loading unit 11 may include a plurality of loading pickers 112.

The loading picker 112 may include an X axis frame 112a and a Y axis frame 112b. The Y axis frame 112b may be coupled to the X axis frame 112a to be movable in the X axis direction. The Y axis frame 112b may be provided with the apparatus for transferring packaged chips 1. The base plate (not shown) may be coupled to the Y axis frame 112b to be movable in the Y axis direction.

Accordingly, the apparatus for transferring packaged chips 1 may move in the X axis direction and the Y axis direction and can ascend and descend. Accordingly, the loading picker 112 may pick up the packaged chips to be tested from the user tray located in the loading stacker 11 and provide the picked-up packaged chips to the test tray T located at the loading position 11a.

The packaged chips are contained in the user tray located in the loading stacker 111 and the test tray in the form of matrixes having different gaps. The gaps in the X axis direction and the Y axis direction of the packaged chips contained in the test tray T may be greater than the gaps in the X axis direction and the Y axis direction of the packaged chips in the user tray. This may connect the packaged chips contained in the test tray T to a hi-fix board H in the chamber system 14.

Accordingly, the apparatus for transferring packaged chips 1 may adjust the gaps of the packaged chips to be tested by adjusting the gaps of the first pickers 3 (FIG. 3) and the second pickers 4 (see FIG. 3) by use of the control unit 5 (FIG. 3).

As described above, since the test handler 10 may transfer more packaged chips at a same time and may employ the apparatus for transferring packaged chips 1 capable of accurately adjusting the gaps of the packaged chips, the loading process, the testing process and the unloading process may be performed on a greater number of packaged chips for a short amount of time.

The loading buffer 113 may temporarily contain the packaged chips to be tested. The loading unit 11 may include a plurality of loading buffers 113.

Based on the loading buffers 113, the loading picker 112 may perform the loading process even when there is no test tray T at the loading position 11a.

The loading picker 112 may pick up the packaged chips to be tested from the user tray located in the loading stacker 111, provide the picked-up packaged chips to the loading buffer 113, then pick up the packaged chips from the loading buffer 113 when a test tray T is located at the loading position 11a, and may provide the picked-up packaged chips to the test tray T located at the loading position 11a.

Accordingly, even when no test tray T is temporarily located at the loading position 11a, the loading process may be continuously performed, thereby preventing loss of process time.

The loading buffer 113 may move in the Y axis direction. Although not shown, the loading buffer 113 may be coupled to a belt that connects a plurality of pulleys to move when a motor rotates at least one pulley.

Referring to FIGS. 9 to 11, the loading transferring unit may transfer the test tray T containing the packaged chips to be tested from the loading position 11a to the passage site 13.

The loading transferring unit may include a loading ascending/descending unit 114 and a loading transferring assembly 115.

The loading ascending/descending unit 114 may allow the test tray T located at the loading position 11a to descend from the loading position 11a to a departing position 11b below the loading position 11a. The loading ascending/descending unit 114 may include a loading ascending/descending member 1141 that supports the test tray T and a cylinder 1142 that moves the loading ascending/descending member 1141 up and down.

The loading transferring assembly 115 may transfer the test tray T located at the departing position 11b from the departing position 11b to the passage site 13 located aside the departing position 11b. The loading transferring assembly 115 may include a plurality of pulleys, a belt that connects the pulleys, and a moving member coupled to the belt to transfer the test tray T by pushing or pulling the test tray T.

Referring to FIGS. 9 and 10, the unloading unit 12 may perform an unloading process of separating tested packaged chips from the test tray T and classifying the separated packaged chips by grades based on the test result. The unloading unit 12 may be provided with the above-described apparatus for transferring packaged chips 1.

The unloading unit 12 may include an unloading stacker 121, an unloading picker 122, an unloading buffer 123 and an unloading transferring unit.

The unloading stacker 121 may store a plurality of user trays containing the tested packaged chips. The tested packaged chips may be contained in the user trays corresponding to the test result from among the user trays located at different positions by grades in the unloading stacker 121.

The unloading picker 122 may perform the unloading process on the test tray T located at an unloading position 12a. At the time of separating the tested packaged chips from the test tray T, the test tray T may be located at the unloading position 12a. The unloading unit 12 may include a plurality of unloading pickers 122.

The unloading picker 122 may include a first unloading picker 1221 and a second unloading picker 1222.

The first unloading picker 1221 may include a Y axis frame 1221a coupled to an X axis frame 112a to be movable along the X axis direction and the apparatus for transferring packaged chips 1 provided in the Y axis frame 1221a. The base plate (not shown) may be coupled to the Y axis frame 1221a to be movable along the Y axis direction.

Accordingly, the apparatus for transferring packaged chips 1 may move in the X axis direction and the Y axis direction and can ascend and descend. As a result, the first unloading picker 1221 can pick up the tested packaged chips from the unloading buffer 123 and provide the picked-up packaged chips to the user tray located in the unloading stacker 121.

The second unloading picker 1222 may include an X axis frame 1222a and the apparatus for transferring packaged chips 1 disposed in the X axis frame 1222a. The base plate (not shown) may be coupled to the X axis frame 1222a to be movable in or along the X axis direction.

Accordingly, the apparatus for transferring packaged chips 1 can move in or along the X axis direction and can ascend and descend. As a result, the second unloading picker 1222 can pick up the tested packaged chips from the test tray T located at the unloading position 12a and provide the picked-up packaged chips to the unloading buffer 123.

The apparatuses for transferring packaged chips 1 disposed in the second unloading picker 1222 and the first unloading picker 1221 can adjust the gaps of the tested packaged chips by adjusting the gaps of the first pickers 3 (FIG. 3) and the second pickers 4 (FIG. 3) by use of the control unit 5 (FIG. 3).

Since the test handler 10 may employ the apparatus for transferring packaged chips 1 that is capable of transferring more packaged chips at a same time and accurately adjusting the gaps of the packaged chips, the loading process, the testing process, and the unloading process may be performed on a greater number of packaged chips for a short amount of time.

The unloading buffer 123 may temporarily contain the tested packaged chips. The unloading unit 12 may include a plurality of unloading buffers 123.

The unloading buffer 123 can move in the or along Y axis direction. Although not shown, the unloading buffer 123 can be coupled to a belt that connects a plurality of pulleys and can move by allowing a motor to rotate at least one pulley.

The distance by which the first unloading picker 1221 and the second unloading picker 1222 move at the time of performing the unloading process can be reduced by the unloading buffer 123 and thus the test handler 10 can perform the unloading process at a higher speed.

Referring to FIGS. 9 to 11, the unloading transferring unit may transfer the test tray T containing the tested packaged chips from the passage site 13 to the unloading position 12a.

The unloading transferring unit may include an unloading ascending/descending unit 124 and an unloading transferring assembly 125.

The unloading ascending/descending unit 124 may allow the test tray T containing the tested packaged chips to ascend from an arriving position 12b (below the unloading position 12a) to the unloading position 12a. The unloading ascending/descending unit 124 may include an unloading ascending/descending member 1241 that supports the test tray T and a cylinder 1242 that allows the unloading ascending/descending member 1241 to ascend and descend.

The unloading transferring assembly 125 may transfer the test tray T containing the tested packaged chips from the passage site 13 to the departing position 12b. Although not shown, the unloading transferring unit 125 may include a plurality of pulleys, a belt that connects the pulleys, and a moving member coupled to the belt to transfer the test tray T by pushing or pulling the test tray T. The departing position 12b may be located below the unloading position 12a and aside the passage site 13.

The unloading unit 12 may further include a waiting buffer 126. The waiting buffer 126 may temporarily contain the tested packaged chips. The first unloading picker 1221 may temporarily contain the tested packaged chips picked up from the unloading buffer 123 in the waiting buffer 126 when no user tray is located in the unloading stacker 121. Accordingly, even when no user tray is located in the unloading stacker 121, the unloading process may be continuously performed, thereby preventing (or reducing) loss of process time.

Referring to FIGS. 9 to 11, the passage site 13 may connect the loading unit 11 and the unloading unit 12 to the chamber system 14. Accordingly, the test tray T containing the packaged chips to be tested can be transferred from the loading unit 11 to the chamber system 14 and the test tray T containing the tested packaged chips can be transferred from the chamber system 14 to the unloading unit 12. The passage site 13 may be provided between the departing position 11b and the arriving position 12b

The passage site 13 may include a rotating unit 131 that rotates the test tray T.

The rotating unit 131 may rotate the test tray T containing the packaged chips to be tested from a horizontal posture (or horizontal position) to a vertical posture (or vertical position). The rotating unit 131 may rotate the test tray T containing the tested packaged chips from the vertical posture to the horizontal posture.

Accordingly, the test handler 10 can perform the loading process and the unloading process on the test tray T with the horizontal posture and can perform the testing process on the test tray T with the vertical posture.

Although not shown, the passage site 13 may be provided with a plurality of pulleys, a belt that connects the pulleys, and transferring means coupled to the belt to transfer the test tray T by pulling or pushing the test tray T. The transferring means may be provided in the chamber system 14.

Referring to FIGS. 9 to 11, the chamber system 14 may include a first chamber 141, a second chamber 142 and a third chamber 143 for the tester to test packaged chips under environments of high temperature, low temperature and normal temperature.

The first chamber 141 may adjust the packaged chips not-yet tested and contained in the test tray T to a first temperature. The first temperature may be in a temperature range of the packaged chips to be tested when the packaged chips to be tested are connected and tested to the hi-fix board H provided in the tester. The test tray T containing the packaged chips to be tested may be a test tray T transferred from the passage site 13.

The first chamber 141 may include at least one of an electric heater and a liquefied nitrogen injecting apparatus to adjust the packaged chips to be tested to a first temperature. The first chamber 141 can allow the test tray T having the vertical posture to move therein.

When the packaged chips to be tested are adjusted to the testing temperature, the test tray T may be transferred from the first chamber 141 to the second chamber 142.

The second chamber 142 may connect the packaged chips adjusted to the first temperature and contained in the test tray T to the hi-fix board H. The second chamber 142 may include a contact unit 1421 that connects the packaged chips adjusted to the first temperature to the hi-fix board H, where a part or all of the hi-fix board H may be inserted into the contact unit 1421. The tester may test the packaged chips to determine electrical characteristics of the packaged chips connected to the hi-fix board H.

The second chamber 142 may include at least one of an electric heater and a liquefied nitrogen injecting apparatus to maintain the packaged chips to be tested at the first temperature. The test handler 1 may include a plurality of second chambers 142 and the hi-fix board H may be separately provided in each of the second chambers 142.

When the packaged chips are completely tested, the test tray T may be transferred from the second chamber 142 to the third chamber 143.

The third chamber 143 may adjust the tested packaged chips contained in the test tray T to a second temperature. The second temperature may be in a temperature range including the normal temperature or a temperature close to the normal temperature. The third chamber 143 may include at least one of an electric heater and a liquefied nitrogen injecting apparatus to restore the tested packaged chips to the second temperature. The third chamber 143 can allow the test tray T having the vertical posture to move therein.

When the tested packaged chips are adjusted to the second temperature, the test tray T may be transferred from the third chamber 143 to the passage site 13.

As shown in FIG. 9, the first chamber 141, the second chamber 142 and the third chamber 143 may be arranged in the horizontal direction. A plurality of second chambers 2 may be vertically stacked.

Although not shown, the first chamber 141, the second chamber 142, and the third chamber 143 may be vertically stacked. In this case, the first chamber 141 may be disposed above the second chamber 142 and the third chamber 143 may be disposed below the second chamber 142.

Referring to FIGS. 9 and 10, the transferring unit 15 can transfer the test tray T that is getting empty in the unloading process from the unloading unit 12 to the loading unit 11. The transferring unit 15 can transfer the test tray T getting empty in the unloading process from the unloading position 12a to the loading position 11a. In this case, the unloading buffer 123 can move toward the unloading stacker 121 without interference from the movement of the test tray T.

Although not shown, the transferring unit 15 may include a plurality of pulleys, a belt that connects the pulleys, and a moving member coupled to the belt to transfer the test tray T by pushing or pulling the test tray T.

A method for manufacturing packaged chips may now be described with reference to FIGS. 3-11.

The packaged chips to be tested may be prepared. This may be performed by storing a user tray containing the packaged chips to be tested in the loading stacker 111. The packaged chips to be tested may include memory or non-memory packaged chips.

The loading unit 11 including the apparatus for transferring packaged chips 1 may perform the loading process of containing the prepared packaged chips in the test tray T. This may be performed by allowing the loading picker 112 to pick up the packaged chips to be tested from the user tray located in the loading stacker 111 and to provide the picked-up packaged chips to the test tray T located at the loading position 11a. The apparatus for transferring packaged chips 1 disposed in the loading picker 112 may adjust the gaps of the packaged chips to be tested by adjusting the gaps of the first pickers 3 and the second pickers 4 by use of the control unit 5.

As described above, since the apparatus for transferring packaged chips 1 that is capable of transferring more packaged chips at a same time and that accurately adjusts gaps of the packaged chips is employed, a greater number of packaged chips may be manufactured for a short amount of time, thereby strengthening competitive power of products such as cost reduction.

When the loading unit 11 includes the loading buffer 113, the loading picker 112 can pick up the packaged chips to be tested from the user tray located in the loading stacker 111 and contain the picked-up packaged chips in the loading buffer 113, and can then pick up the packaged chips to be tested from the loading buffer 113 when the test tray T is located at the loading position 11a and contain the picked-up packaged chips in the test tray T located at the loading position 11a.

The test tray T containing the packaged chips to be tested may be transferred from the loading position 11a where the test tray is located at a time of performing the loading process to the passage site 13. This may be performed by allowing the loading transferring unit to transfer the test tray T containing the packaged chips in the loading process from the loading position 11a to the passage site 13.

Then, the test tray T may be transferred from the passage site 13 to the chamber system 14. This may be performed by allowing the transferring means (not shown) disposed in the passage site 13 or the chamber system 14 to transfer the test tray T, which is transferred from the loading position 11a, from the passage site 13 to the first chamber 141.

In the chamber system 14, the packaged chips contained in the test tray T may be adjusted to the first temperature, the packaged chips adjusted to the first temperature may be connected and tested to the hi-fix board H, and the tested packaged chips may be adjusted to the second temperature. This may be performed by allowing the first chamber 141 to adjust the packaged chips in the test tray T to the first temperature, allowing the second chamber 142 to connect and test the packaged chips adjusted to the first temperature to the hi-fix board H, and allowing the third chamber 143 to adjust the tested packaged chips to the second temperature.

The test tray T containing the tested packaged chips may be transferred from the chamber system 14 to the passage site 13. This may be performed by allowing the transferring means (not shown) disposed in the passage site 13 or the chamber system 14 to transfer the test tray T containing the tested packaged chips from the third chamber 143 to the passage site 13.

The test tray T located in the passage site 13 to the unloading position 11a where the test tray T is located at the time of separating the tested packaged chip from the test tray T. This may be performed by allowing the unloading transferring unit to transfer the test tray T containing the tested packaged chips tested in the chamber system 14 from the passage site 13 to the unloading position 12.

The unloading unit 12 including the apparatus for transferring packaged chips 1 may perform the unloading process of separating the tested packaged chips from the test tray T located at the unloading position 12a and classify the separated packaged chips by grades based on the test result. This may be performed by allowing the second unloading picker 1222 to pick up the tested packaged chips from the test tray T located at the unloading position 12a and to contain the picked-up packaged chips in the unloading buffer 123 and allow the first unloading picker 1221 to pick up the tested packaged chips from the unloading buffer 123 and to contain the picked-up packaged chips in the user tray located in the unloading stacker 121.

The first unloading picker 1221 can contain the tested packaged chips in the user tray corresponding to the test result from among the user trays located at different positions by grades in the unloading stacker 121.

The apparatuses for transferring packaged chips 1 disposed in the first unloading picker 1221 and the second unloading picker 1222 can adjust the gaps of the tested packaged chips by adjusting the gaps of the first pickers 3 and the second pickers 4 by use of the control unit 5.

As described above, since the apparatus for transferring packaged chips 1 that is capable of transferring more packaged chips at a same time and that accurately adjusts the gaps of the packaged chips is employed, more packaged chips may be manufactured for a short amount of time, thereby strengthening competitive power of products such as cost reduction.

The test tray T getting empty in the unloading process may be transferred from the unloading position 12a to the loading position 11a. This may be performed by allowing the transferring unit 15 to transfer the test tray T getting empty in the unloading process from the unloading position 12a to the loading position 11a.

In the method for manufacturing packaged chips, transferring the test tray T containing the packaged chips to be tested from the loading position 11a (where the test tray T is located at the time of performing the loading process) to the passage site 13 may further include the following.

The test tray T containing the packaged chips to be tested may descend from the loading position 11a to the departing position 11b below the loading position 11a. This may be performed by allowing the loading ascending/descending unit 114 to move the test tray T (having been subjected to the loading process) down from the loading position 11a to the departing position 11b.

The test tray T may be transferred from the departing position 11b to the passage site 13. This may be performed by allowing the loading transferring assembly 115 to transfer the test tray T from the departing position 11b to the passage site 13.

In the method for manufacturing packaged chips, transferring the test tray T located in the passage site 13 to the unloading position where the test tray T is located at the time of separating the tested packaged chips from the test tray T may include the following.

The test tray T containing the tested packaged chips may be transferred from the passage site 13 to the arriving position 12b below the unloading position 12a. This may be performed by allowing the unloading transferring assembly 125 to transfer the test tray T containing the tested packaged chips tested in the chamber system 14 from the passage site 13 to the arriving position 12b.

The test tray T located at the arriving position 12b may ascend to the unloading position 12a. This may be performed by allowing the unloading ascending/descending unit 124 to move the test tray T up from the arriving position 12b to the unloading position 12a.

By repeatedly performing the above-described processes, manufacturing of the packaged chips may be completed.

An apparatus for transferring packaged chips may be provided that includes a main frame having a coupling member coupled to a base plate and a supporting member coupled to the coupling member, a plurality of first pickers coupled to one side of the supporting member so as to be movable in a horizontal direction, a plurality of second pickers coupled to the other side of the supporting member so as to be movable in the horizontal direction, and a control unit determining distances by which the first pickers and the second pickers move in the horizontal direction.

A test handler may be provided that includes a loading unit performing a loading process of containing packaged chips to be tested in a test tray, an unloading unit performing an unloading process of separating tested packaged chips from the test tray and classifying the separated packaged chips by grades based on the test result, and a chamber system in which the packaged chips contained in the test tray are connected to a hi-fix board and tested. The test handler may also include a passage site connecting the loading unit and the unloading unit to the chamber system so as to transfer the test tray containing the packaged chips to be tested from the loading unit to the chamber system and to transfer the test tray containing the tested packaged chips from the chamber system to the unloading unit. Still further, the test handler may include a transferring unit transferring the test tray getting empty in the unloading process from the unloading unit to the loading unit, and an apparatus for transferring packaged chips disposed in each of the loading unit and the unloading unit.

A method for manufacturing packaged chips may include preparing packaged chips to be tested, allowing a loading unit having an apparatus for transferring packaged chips to perform a loading process of containing the packaged chips to be tested in a test tray, transferring the test tray containing the packaged chips to be tested from a loading position (where the test tray is located at the time of performing the loading process) to a passage site, and transferring the test tray located in the passage site to a chamber system. The method may also include allowing the chamber system to adjust the packaged chips contained in the test tray to a first temperature, to connect and test the packaged chips adjusted to the first temperature to a hi-fix board, and to adjust the tested packaged chips to a second temperature. Still further, the method may include transferring the test tray containing the tested packaged chips from the chamber system to the passage site, transferring the test tray from the passage site to an unloading position where the test tray is located at the time of separating the tested packaged chips from the test tray, allowing an unloading unit having the apparatus for transferring packaged chips to perform an unloading process of separating the tested packaged chips from the test tray and classifying the separated packaged chips by grades based on the test result, and transferring the test tray getting empty in the unloading process from the unloading position to the loading position.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus for transferring packaged chips comprising:
a main frame having a coupling member coupled to a base plate and a supporting member coupled to the coupling member;
a plurality of first pickers coupled to one side of the supporting member and movable in a horizontal direction;
a plurality of second pickers coupled to the other side of the supporting member and movable in the horizontal direction; and
a control unit to determine distances by which each of the first pickers and the second pickers move in the horizontal direction.

2. The apparatus according to claim 1, wherein each of the first pickers includes a first nozzle frame having at least one nozzle to contact a packaged chip,
wherein each of the second pickers includes a second nozzle frame having at least one second nozzle to contact a packaged chip, and
wherein the first pickers and the second pickers are coupled to the supporting member such that the second nozzle frame is provided aside the first nozzle frame.

3. The apparatus according to claim 2, wherein each of the first pickers further includes a first coupling frame that is movable coupled to the supporting member,
wherein each of the second pickers further includes a second coupling frame that is movable coupled to the supporting member,
wherein the first pickers are coupled to the one side of the supporting member such that the first coupling frame of one of the first pickers is provided aside the first coupling frame of another first picker, and
wherein the second pickers are coupled to the other side of the supporting member such that the second coupling frame of one of the second pickers is provided aside the second coupling frame of another second picker.

4. The apparatus according to claim 1, wherein the main frame includes:
at least one first guide rail provided on the one side of the supporting member to guide movement of the first pickers; and
at least one second guide rail provided on the other side of the supporting member to guide movement of the second pickers.

5. The apparatus according to claim 4, wherein each of the first pickers includes at least one first guide block that is movable coupled to the at least one first guide rail, and
wherein each of the second pickers includes at least one second guide block that is movably coupled to the at least one second guide rail.

6. The apparatus according to claim 5, wherein each of the first pickers further includes a first coupling frame having a plurality of first coupling holes to couple with the first guide block, and
wherein each of the second picker further includes a second coupling frame having a plurality of second coupling holes to couple with the second guide block.

7. The apparatus according to claim 1, wherein the control unit includes a guide plate to couple to the coupling member and movable in a vertical direction, and
wherein the guide plate includes a plurality of first guide holes movably coupled to the first pickers and a plurality of second guide holes movably coupled to the second pickers.

8. The apparatus according to claim 7, wherein each of the first pickers includes a first moving member that is movably coupled to the first guide hole and moves relative to the first guide hole,
wherein each of the second pickers includes a second moving member that is movably coupled to the second guide hole and moves relative to the second guide hole, and
wherein the second moving member is movably coupled to the second guide hole through the second supporting member.

9. The apparatus according to claim 1, wherein the first pickers are coupled to a surface of the supporting member that is opposite a surface to which the second pickers are coupled.

10. A test handler comprising:
a loading unit to perform a loading process of providing packaged chips to be tested to a test tray;
an unloading unit to perform an unloading process of separating tested packaged chips from the test tray and to classify the separated packaged chips by grades based on a test result;
a chamber system to receive the packaged chips in the test tray and to connect the packaged chips to a hi-fix board for testing;
a passage site to connect the loading unit to the chamber system such that the test tray containing the packaged chips to be tested is transferred from the loading unit to the chamber system and to connect the chamber system to the unloading unit such that the test tray containing the tested packaged chips is transferred from the chamber system to the unloading unit;
a transferring unit to transfer the test tray from the unloading unit to the loading unit; and
an apparatus to transfer packaged chips provided in each of the loading unit and the unloading unit that includes:
a main frame having a coupling member coupled to a base plate and a supporting member coupled to the coupling member,
a plurality of first pickers coupled to one side of the supporting member and movable in a horizontal direction,
a plurality of second pickers coupled to the other side of the supporting member and movable in the horizontal direction, and
a control unit to determine distances by which each the first pickers and the second pickers move in the horizontal direction.

11. The test handler to claim 10, wherein each of the first pickers includes a first nozzle frame having at least one nozzle to contact a packaged chip,
wherein each of the second pickers includes a second nozzle frame having at least one second nozzle to contact a packaged chip, and
wherein the first pickers and the second pickers are coupled to the supporting member such that the second nozzle frame is provided aside the first nozzle frame.

12. The test handler according to claim 11, wherein each of the first pickers further includes a first coupling frame that is movable coupled to the supporting member,
wherein each of the second pickers further includes a second coupling frame that is movable coupled to the supporting member,
wherein the first pickers are coupled to the one side of the supporting member such that the first coupling frame of one of the first pickers is provided aside the first coupling frame of another first picker, and
wherein the second pickers are coupled to the other side of the supporting member such that the second coupling frame of one of the second pickers is provided aside the second coupling frame of another second picker.

13. The test handler according to claim 10, wherein the control unit includes a guide plate to couple to the coupling member and movable in a vertical direction, and
wherein the guide plate includes a plurality of first guide holes movably coupled to the first pickers and a plurality of second guide holes movably coupled to the second pickers.

14. The test handler according to claim 13, wherein each of the first pickers includes a first moving member that is movably coupled to the first guide hole and moves relative to the first guide hole,
wherein each of the second pickers includes a second moving member that is movably coupled to the second guide hole and moves relative to the second guide hole, and
wherein the second moving member is movably coupled to the second guide hole through the second supporting member.

15. The test handler according to claim 10, wherein the first pickers are coupled to a surface of the supporting member that is opposite a surface to which the second pickers are coupled.

16. The test handler according to claim 10, wherein the loading unit includes a loading transferring unit to transfer the test tray containing the packaged chips to be tested from a loading position where the test tray is located at a time of performing the loading process to the passage site, and
wherein the loading transferring unit includes a loading ascending/descending unit to move the test tray containing the packaged chips to be tested from the loading position to a departing position that is below the loading position.

17. The test handler according to claim 10, wherein the unloading unit includes an unloading transferring unit to transfer the test tray containing the tested packaged chips from the passage site to an unloading position where the test tray is located at a time of performing the unloading process, and
wherein the unloading transferring unit includes an unloading ascending/descending unit to move the test tray containing the tested packaged chips from a departing position below the unloading position to the unloading position.

18. A method for manufacturing packaged chips comprising:
preparing packaged chips to be tested;
allowing a loading unit having an apparatus for transferring packaged chips to perform a loading process of providing the packaged chips to be tested to a test tray;
transferring the test tray containing the packaged chips to be tested from a loading position where the test tray is located at a time of performing the loading process to a passage site;
transferring the test tray located in the passage site to a chamber system;
adjusting the packaged chips contained in the test tray to a first temperature, connecting the packaged chips adjusted to the first temperature to a hi-fix board for testing, and adjusting the tested packaged chips to a second temperature;
transferring the test tray containing the tested packaged chips from the chamber system to the passage site;
transferring the test tray from the passage site to an unloading position where the test tray is located at a time of separating the tested packaged chips from the test tray;
allowing an unloading unit having the apparatus for transferring packaged chips to perform an unloading process of separating the tested packaged chips from the test tray and classify the separated packaged chips by grades based on a test result; and
transferring the test tray from the unloading position to the loading position,
wherein the apparatus for transferring packaged chips provided in each of the loading unit and the unloading unit includes:
a main frame having a coupling member coupled to a base plate and a supporting member coupled to the coupling member,
a plurality of first pickers coupled to one side of the supporting member and movable in a horizontal direction,
a plurality of second pickers coupled to the other side of the supporting member and movable in the horizontal direction, and
a control unit to determine distances by which each of the first pickers and the second pickers move in the horizontal direction.

19. The method according to claim 18, wherein transferring the test tray containing the packaged chips to be tested from the loading position to the passage site includes:
descending the test tray containing the packaged chips to be tested from the loading position to a departing position that is below the loading position; and
transferring the test tray from the departing position to the passage site.

20. The method according to claim 18, wherein transferring the test tray from the passage site to the unloading position includes:
transferring the test tray containing the tested packaged chips from the passage site to an arriving position that is below the unloading position; and
ascending the test tray from the arriving position to the unloading position.
